(19) United States
(12) Patent Application Publication
(10) Pub. No.: US 2018/0083000 A1
(43) Pub. Date: Mar. 22, 2018

(54) FIN EPITAXY WITH LATTICE STRAIN RELAXATION

(71) Applicant: QUALCOMM Incorporated, San Diego, CA (US)

(72) Inventor: Sinan GOKTEPELI, San Diego, CA (US)

(21) Appl. No.: 15/271,120

(22) Filed: Sep. 20, 2016

(51) Int. Cl. H01L 27/088; H01L 29/78; H01L 29/66; H01L 21/306; H01L 29/16; H01L 21/762; H01L 21/265; H01L 21/3065; H01L 29/20; H01L 29/06; H01L 29/10

(52) U.S. Cl. CPC H01L 27/0886; H01L 29/785; H01L 29/66795; H01L 21/30604; H01L 29/16; H01L 29/1054; H01L 21/26513; H01L 21/3065; H01L 29/20; H01L 29/0676; H01L 21/76224

(57) ABSTRACT

A semiconductor having a first lattice constant is deposited on an exposed sidewall of a relatively small group IV semiconductor substrate fin having a second lattice constant that does not equal the first lattice constant to form a semiconductor fin without any crystal defects resulting from a lattice mismatch between the first lattice constant and the second lattice constant.

### TECHNICAL FIELD

This application relates generally to transistors, and more particularly to fin epitaxy without crystal dislocations on a group IV substrate.

### BACKGROUND

To provide additional processing speed, development has begun on fin-shaped field effect transistor (FinFET) and nanowire transistors in which the fin (or nanowire) is constructed from high-mobility III-V semiconductors such as GaAs, InP, GaP, and GaN. But silicon remains as the substrate of choice due to is low cost. An example III-V FinFET 100 is shown in FIG. 1A. A III-V fin 115 adjoins a silicon substrate 120 and is surrounded by a dielectric 125 (e.g., SiO₂). The III-V fin 115 is grown on silicon substrate 120 such as through epitaxial deposition. But the lattice constants (the spacing between atoms in the crystal lattice) differ between Si and III-V semiconductors. For example, the lattice constant for Si at 300K (80 degrees Fahrenheit) is 5.4 Angstroms, while the lattice constant for GaP at the same temperature is 5.45 Angstroms. This slight mismatch between the lattice constants leads to an eventual crystal dislocation between the silicon substrate and the deposited III-V semiconductor. The crystal dislocation forms a plane of free carriers in the deposited fin. If the crystal dislocation extends across the width of fin 115 as shown for crystal dislocation planes 105, the defect may be relatively harmless. But other crystal dislocation planes 110 extend in the longitudinal direction for fin 115. Should one of the crystal dislocation planes 110 thus extend from the source to the drain across fin 115, FinFET 100 is defective since the drain and source are effectively shorted together (the gate is not shown in FIG. 1A for illustration clarity). The lattice mismatch problem is not limited to the epitaxy of III-V fins on silicon substrates. For example, the lattice constants are different between germanium and silicon. An epitaxial growth of a germanium fin on a silicon substrate will thus suffer from crystal dislocations due to the lattice mismatch.

Accordingly, there is a need in the art for improved hetero-epitaxy of three-dimensional devices such as FinFETs and nanowire devices on silicon substrates without defects from lattice mismatch.

### SUMMARY

To provide defect-free hetero-epitaxy of three-dimensional devices on group IV semiconductor substrates, a first semiconductor having a first lattice constant is deposited on a sidewall of a relatively-small seed structure formed from a group IV semiconductor substrate having a second lattice constant that is different from the first lattice constant. The relatively small dimensions of the sidewall prevents crystal dislocations despite the inherent lattice mismatch strain in a hetero-epitaxy process: e.g., the sidewall may have a length of 10 to 40 nanometers and a height of 5 to 20 nanometers. With such small dimensions, there are thus relatively few group IV semiconductor atoms stacked in either the height or length dimensions of the exposed sidewall. The dimensions of the exposed sidewall prevent the formation of a crystal dislocation plane in the deposited first semiconductor material as there are simply not enough group IV semiconductor atoms (in either the length or the height) of the exposed sidewall to produce enough cumulative lattice mismatch stress between the group IV semiconductor and the first semiconductor to cause a crystal dislocation plane in the epitaxially grown first semiconductor on the exposed sidewall.

Since the epitaxial growth of the first semiconductor occurs only on the exposed sidewall of the group IV semiconductor seed structure, the width of the seed structure is irrelevant. However, the spacing between adjacent seed structures must be such that the first semiconductor deposition is allowed to grow freely in the lateral direction orthogonal to the plane defined by the exposed sidewall. In this fashion, the first semiconductor growth on the exposed sidewall surface during epitaxial deposition is allowed to relax in all three directions defined by the plane of the exposed sidewall: in the height direction away from the underlying group IV semiconductor substrate; in the longitudinal direction along the length of the exposed sidewall planar surface; and in the lateral direction parallel to the planar surface of the underlying group IV semiconductor surface and orthogonal to the planar surface of the exposed sidewall.

Given this relaxation in all three dimensions, the resulting first semiconductor epitaxial growth does not result in crystal dislocation planes: neither across the width of the deposited first semiconductor nor along the longitudinal axis of the deposited first semiconductor. The resulting device formation (whether as a FinFET or as a nanowire device) is thus advantageously defect free.

These and additional advantages may be better appreciated through the following detailed description.

### BRIEF DESCRIPTION OF THE DRAWINGS

FIG. 1A is a perspective view of a conventional III-V FinFET device on a silicon substrate.

FIG. 1B illustrates the lattice mismatch at an interface between silicon and a III-V semiconductor.

FIG. 2A is a cross-sectional view of the silicon substrate after deposition of an etch stop layer.

FIG. 2B is plan view of the silicon substrate of FIG. 2A after etching and deposition of the shallow trench isolation cuts.

FIG. 2C is a cross-section view of the silicon substrate of FIG. 2B after etching of the silicon fins and deposition of the dielectric layer covering the silicon substrate portions between the silicon fins.

FIG. 2D is a plan view of the silicon substrate of FIG. 2C.

FIG. 2E is a cross-sectional view of the silicon substrate of FIG. 2C after deposition of the III-V fins.

FIG. 2F is a plan view of the silicon substrate of FIG. 2E.

FIG. 2G is a cross-sectional view of the silicon substrate of FIG. 2E in an alternative embodiment including a liner layer.

FIG. 2H is a cross-sectional view of the silicon substrate of FIG. 2E after removal of the silicon fins and their etch stop upper layers.

FIG. 2I is a plan view of the silicon substrate of FIG. 2H.

FIG. 3A is a cross-sectional view of the silicon substrate of FIG. 2H after formation of III-V FinFETs incorporating the III-V fins.

FIG. 3B is a plan view of the silicon substrate of FIG. 3A.

FIG. 4 is a flowchart for a method of manufacturing defect-free III-V fins on a IV semiconductor substrate.

Embodiments of the present invention and their advantages are best understood by referring to the detailed description that follows. It should be appreciated that like reference numerals are used to identify like elements illustrated in one or more of the figure.

### DETAILED DESCRIPTION

The following hetero-epitaxy process for a three-dimensional device will be explained with regard to relieving the lattice mismatch stress between a silicon substrate and a III-V semiconductor. However, it will be appreciated that the same techniques are readily applied to relieve the lattice mismatch stress between a group IV semiconductor substrate having a first lattice constant and other semiconductor materials having a second lattice constant that does not equal the first lattice constant. For example, the following hetero-epitaxy process may be used to form a germanium fin on the exposed sidewall of a seed structure on a silicon substrate. More generally, the seed structure and the corresponding substrate may comprise a group IV semiconductor. Silicon is plainly the least expensive such group IV semiconductor substrate such that the following discussion will be directed to embodiments in which the seed structures and the substrate are silicon. The following discussion will thus be directed to the deposition of III-V semiconductor on a silicon substrate without loss of generality.

To prevent defects from crystal dislocations resulting from a lattice mismatch between a silicon seed structure on a silicon substrate and a III-V semiconductor, the III-V semiconductor is epitaxially deposited on a relatively-small exposed sidewall of the silicon seed structure. The exposed sidewall forms a plane that is orthogonal to a planar surface of the silicon substrate. The plane of the exposed sidewall thus extends in a height direction that extends orthogonally to the planar surface of the silicon substrate. In addition, the plane of the exposed sidewall extends in a longitudinal direction that is parallel to the planar surface of the silicon substrate.

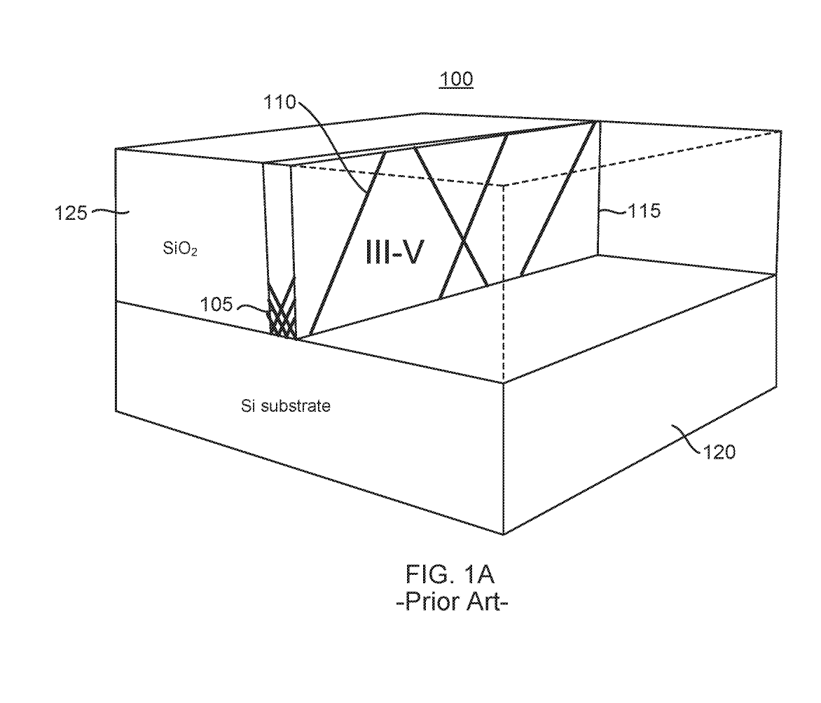

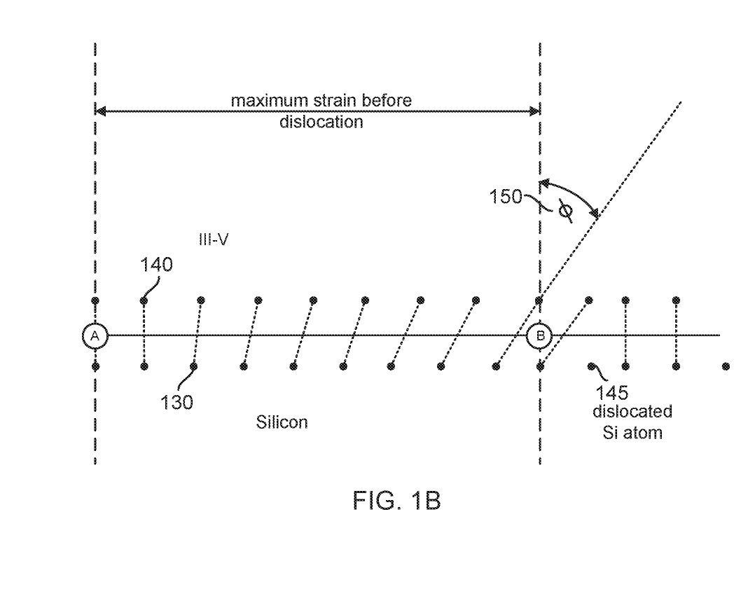

With regard to these two dimensions that define the plane for the exposed sidewall of the silicon seed structure, neither the height nor the length extends beyond a maximum stress limit from the lattice mismatch. This stress limit may be better understood with regard to FIG. 1B which shows a planar interface between silicon and a III-V semiconductor. Each silicon atom 130 at the interface is spaced apart by the silicon lattice constant. Similarly, each III-V molecule 140 at the interface is spaced apart by a III-V lattice constant that is slightly larger than the silicon lattice constant. At a point A in the interface, a silicon atom 130 is aligned directly with a III-V molecule 140. But due to the lattice mismatch, the bonds between adjacent silicon atoms 130 and III-V molecules 140 becomes more and more strained until a maximum strain is reached at a point B at the interface. Past this point B, a crystal dislocation is formed since a dislocated silicon atom 145 can form no bond with a III-V molecule 140 across the interface due to the cumulative lattice mismatch between points A and B. There is thus a limit to the number of successive silicon atoms 130 at the interface that can be aligned before reaching the maximum strain and producing a dislocation. Advantageously, the height and length of the exposed silicon sidewall is limited such that the maximum strain is never exceeded.

For example, the height of the silicon sidewall is limited to range from 5 nm to approximately 20 nm. With such a relatively short height, the number of silicon atoms from any given point at the bottom of the sidewall and extending orthogonally away from the silicon substrate towards the top of the sidewall does not exceed the maximum number of silicon atoms that can be aligned in succession before a dislocation is reached with bonding across the interface to the III-V semiconductor. The length of the sidewall is also restrained such as not exceeding from 10 nm to approximately 40 nm in length. Referring again to FIG. 1B, the distance from point A to point B may be assumed to correspond to the length of the sidewall. As more III-V molecules are deposited over the initial layer from point A to point B, the extra layers of III-V molecules 140 will tend to extend further than point B due to the lattice mismatch such that an edge of the III-V semiconductor forms a relaxation angle φ 150 should the silicon end at point B. A similar relaxation angle would be formed at point A but is not shown for illustration clarity.

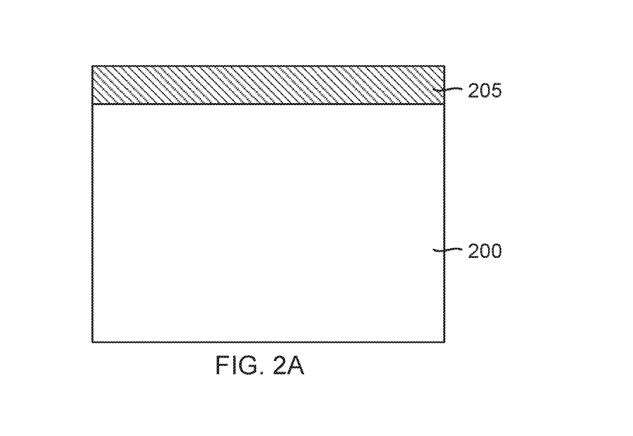

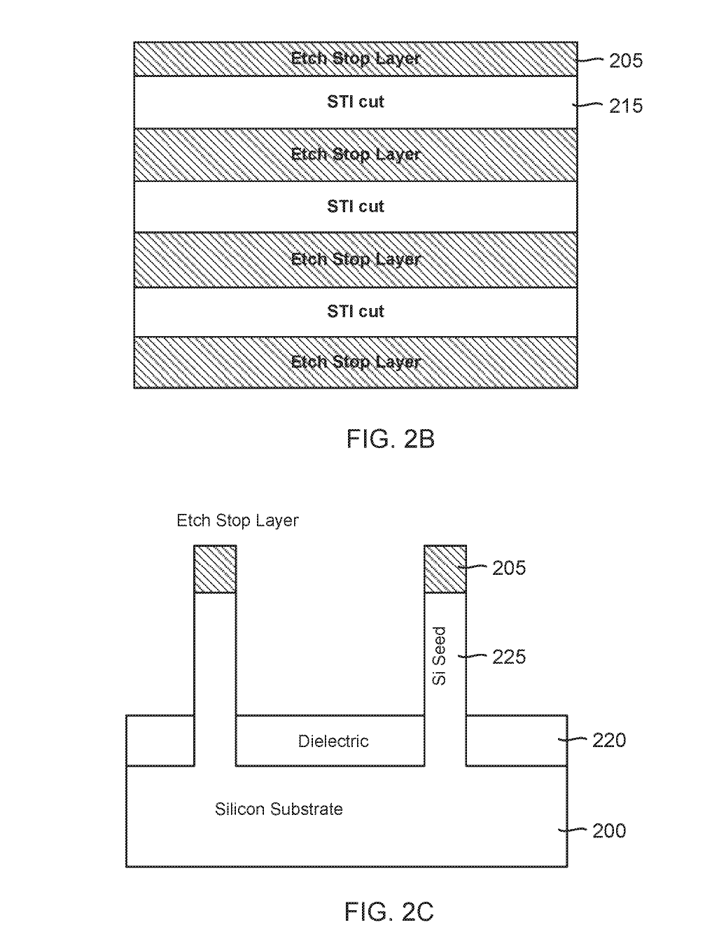

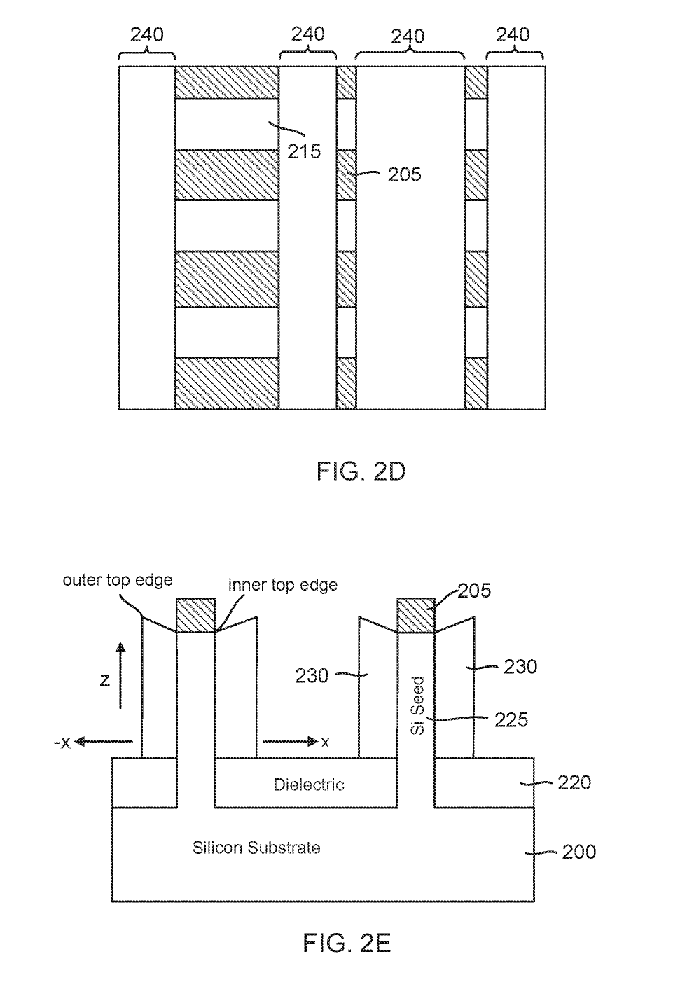

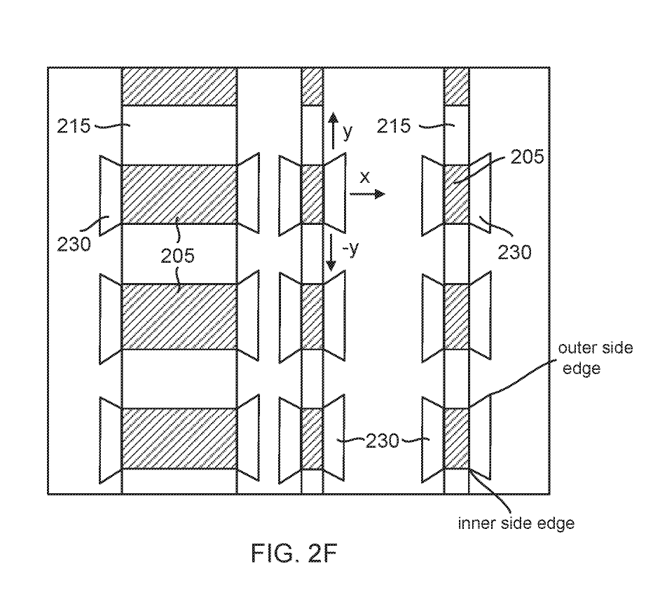

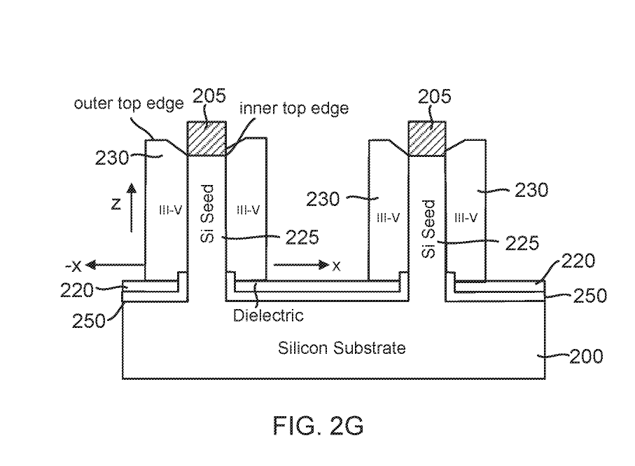

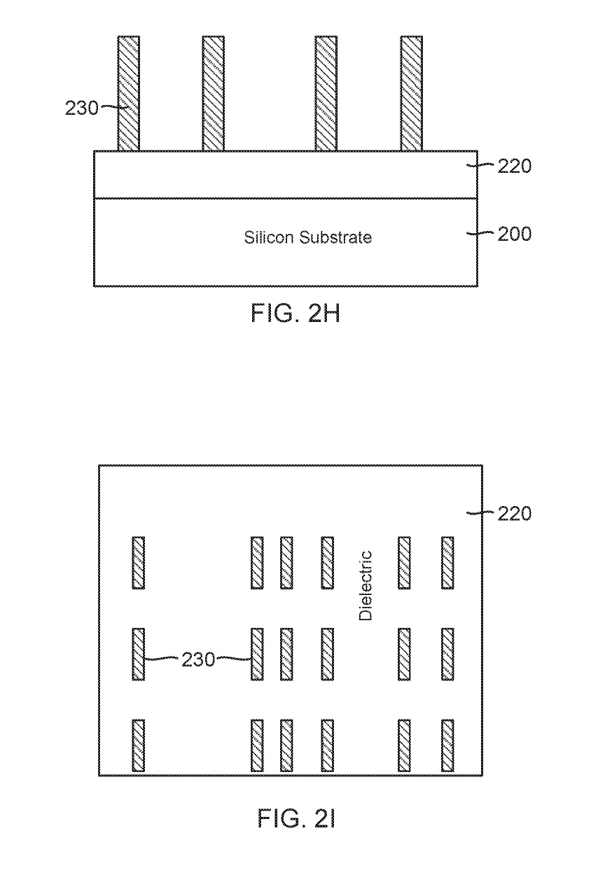

A manufacturing process to achieve this advantageous relaxation of the lattice mismatch strain in the III-V fin will now be discussed. The process begins as shown in FIG. 2A with the formation of an etch stop layer 205 on a surface of a silicon substrate 200. The etch stop layer 205 may be either epitaxially deposited or formed through ion implantation of a suitable etch stop ion such as boron, germanium, or boron/germanium.

The process continues with the patterning of etch stop layer 205 and substrate 200 with trenches and the deposition of dielectric (e.g., SiO₂) to fill the trenches to form shallow trench isolation structures (which may also be denoted as “cuts”) 215 as shown in FIG. 2B. As known in the shallow trench isolation arts, the deposited dielectric may then be smoothed using chemical-mechanical planarization.

Etch stop layer 205, STI cuts 215, and substrate 200 are then etched with trenches 240 to form silicon fins 225 as shown in cross-section in FIG. 2C and in a plan view in FIG. 2D. Dielectric material is then deposited in the trenches 240 such that a base of each silicon fin 225 is isolated from a base of a neighboring silicon fin 225 by a dielectric layer 220 that partially fills trenches 240. The deposition of the dielectric material may fill each trench 240 and be followed by chemical-mechanical planarization. Each trench 240 may then be re-etched to result in dielectric layers 220 partially filing trenches 240. Note that a longitudinal axis of each trench 240 is orthogonal to a longitudinal axis for each STI cut 215. Trenches 240 thus transect each STI cut 215.

Each silicon fin 225 has two exposed faces as seen in the cross-sectional view of FIG. 2C. An epitaxial deposition of III-V semiconductor forms a III-V fin 230 on each exposed face as shown in a cross-sectional view of FIG. 2E and also in a plan view of FIG. 2F. Note that silicon fins 225 are spaced apart in a lateral direction that is parallel to a surface of the underlying silicon substrate 200. This lateral direction is designated as the x axis and its opposite −x axis in FIG. 2E. A lateral direction orthogonal to the x direction is denoted as the y axis. The x and y Cartesian coordinates thus define the surface of the underlying silicon substrate 200 that silicon fins 225 rise above. The lateral spacing of silicon fins 225 in the x Cartesian coordinate is quite advantageous as the III-V crystal lattice may relax in both the y and z direction. The z direction is orthogonal to the planar surface of underlying silicon substrate 200 and measures the height of each silicon fin 225. As discussed with regard to FIG. 1B, an upper edge of each III-V fin 230 is angled with regard to a base of etch stop layer 205 such that an outer upper edge of each III-V fin 230 is higher than an inner upper edge of each III-V fin 230. This relaxation also occurs in the y and −y directions such that an outer side edge of each III-V fin 230 is not even in the y dimension with a corresponding inner side edge. Referring again to FIG. 1B, the angle formed between the outer top edge and the inner top edge for each III-V fin 230 relates to the lattice mismatch such as shown by relaxation angle 150. A similar angle (although not necessarily equal) produces the difference between the outer side edge and inner side edge for each III-V fin 230.

In FIG. 2E, it may be seen that each III-V fin 230 can only relax in the positive z direction but not in the negative z direction. To allow some relaxation in the negative z direction, trenches 240 (FIG. 2D) may first be lined with a dielectric liner 250 (which may also be denoted as a spacer) as shown in FIG. 2G prior to formation of dielectric layers 220. The z height of liner 250 at the base of each silicon fin 225 is higher than a height of an upper surface for each dielectric layer 220. III-V fins 230 in FIG. 2G may thus relax in both the positive and negative z directions, to further reduce the lattice mismatch strain. Due to the relaxation of the lattice mismatch strain, each III-V fin 230 will have an outer sidewall that is larger than an inner sidewall abutting the corresponding silicon fin sidewall. The inner sidewall of each III-V fin 230 will have substantially the same height and length as the formerly exposed sidewall of each corresponding silicon fin 225.

Regardless of whether liner 250 is present or not, each silicon fin 225 and corresponding etch stop layer 205 may be removed such as through wet etching or reactive ion etching to complete the production of III-V fins 230. A liner-less embodiment after silicon fin 225 removal is shown in cross-section in FIG. 2H and in a plan view in FIG. 2I. Referring again to FIG. 2E, note the III-V epitaxial deposition may involve a first layer of SiGe (which is not a III-V semiconductor) followed by a layer of Ge (again not a III-V semiconductor) followed by a layer of InP and InGaAs to ease the transition from silicon to actual III-V semiconductor. The etching step discussed with regard to FIGS. 2H and 2I could then remove some of the layers in the epitaxial deposition of the III-V semiconductor such as by removing the SiGe or Ge layers.

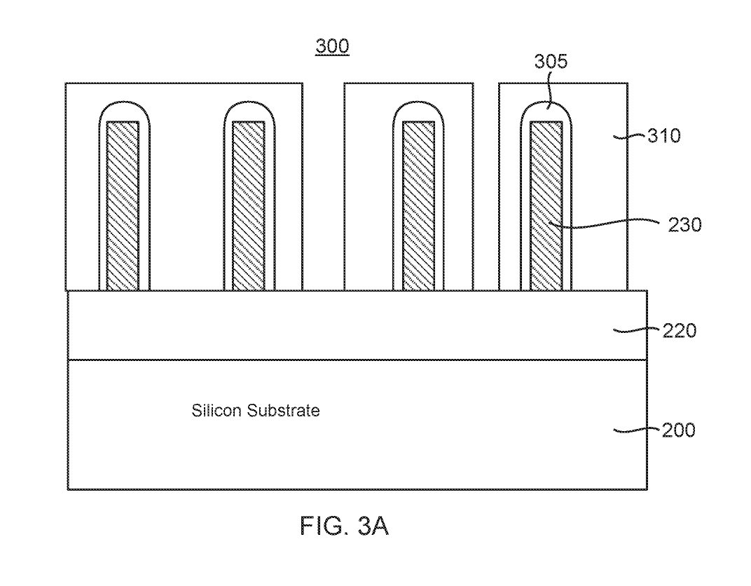

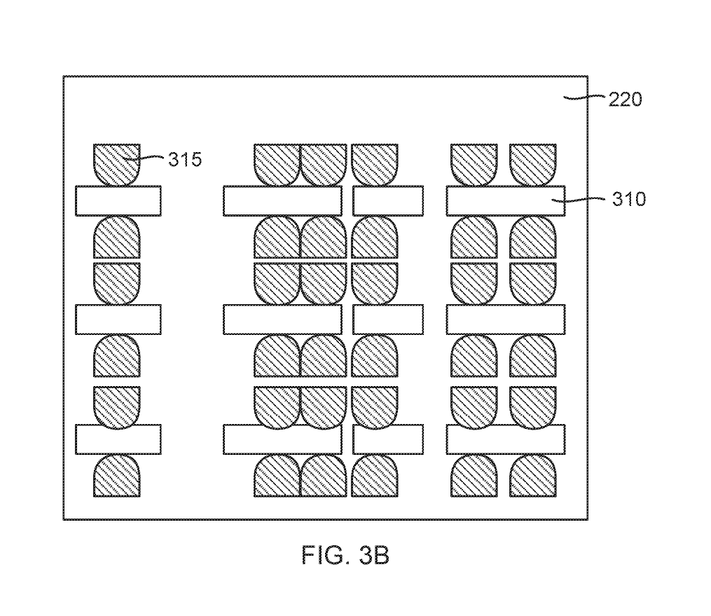

With the III-V fins 230 completed, III-V transistors may be formed using conventional FinFET processing steps as shown in cross-section in FIG. 3A and in plan view in FIG. 3B. For example, a dummy gate process may be used to form a dummy gate (not illustrated) during the formation of gates 310 and gate dielectric 305. Drain/source contacts 315 may then be epitaxially deposited followed by conventional middle-end-of-line and back-end-of-line processes to complete the desired III-V devices.

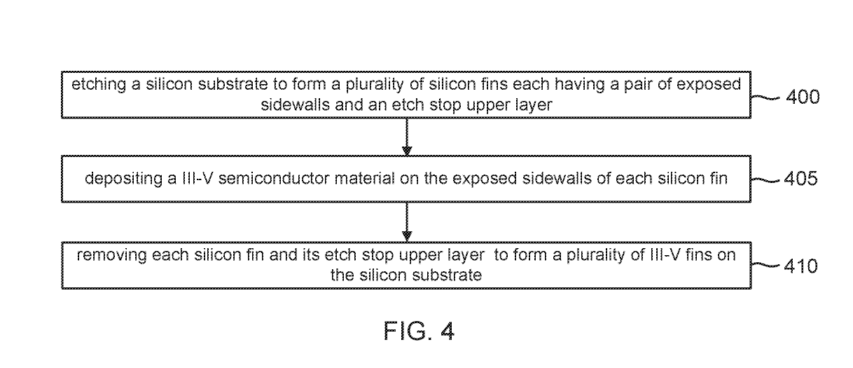

The manufacturing method may be summarized as follows with regard to the flowchart of FIG. 4. The method includes an act 400 of etching a silicon substrate to form a plurality of silicon fins each having a pair of exposed sidewalls and an etch stop upper layer. The etching of silicon substrate 200 discussed with regard to FIG. 2D is an example of act 400. The method also includes an act 405 of depositing a III-V semiconductor material on the exposed sidewalls of each silicon fin. The deposition of III-V fins 230 as discussed with regard to FIGS. 2E, 2F, and 2G is an example of act 405. Finally, the method includes an act 410 of removing each silicon fin and its etch stop upper layer to form a pair of III-V fins on the silicon substrate for each removed silicon fin. The removal of silicon fins 225 as discussed with regard to FIGS. 2H and 2I is an example of act 410.

Those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

1-11. (canceled)

12. A device, comprising:
a group IV semiconductor substrate having a first lattice constant;
a dielectric layer covering the group IV semiconductor substrate;
a plurality of semiconductor fins on a surface of the dielectric layer, wherein the plurality of semiconductor fins comprise a first semiconductor having a second lattice constant that does not equal the first lattice constant, and wherein an inner sidewall of each semiconductor fin has a length and a height that prevent crystal dislocations with regard to an epitaxial deposition on the group IV semiconductor substrate, and wherein a height for an outer sidewall of each semiconductor fin has a height that is greater than the height of the semiconductor fm's inner sidewall.

13. The device of claim 12, wherein the length is approximately 10 to 40 nanometers and the height is approximately 5 to 20 nanometers.

14. The device of claim 13, wherein the group IV semiconductor substrate is a silicon substrate.

15. The device of claim 14, wherein the first semiconductor is a group III-V semiconductor.

16. The device of claim 14, wherein the dielectric layer comprises silicon dioxide.

17. The device of claim 14, wherein the dielectric layer comprises a first dielectric layer and a second dielectric layer.

18. The device of claim 15, wherein a width of each semiconductor fin is wider at the outer sidewall of the semiconductor fin than at the inner sidewall of the semiconductor fin.

19-22. (canceled)

23. The device of claim 17, wherein the first dielectric layer extends to the inner sidewall of each semiconductor fin, and wherein the second dielectric layer does not extend to the inner sidewall of each semiconductor fin.

24. The device of claim 23, wherein the second dielectric layer extends over the first dielectric layer except at a portion of the first dielectric layer adjacent the inner sidewall of each semiconductor fin.

25. The device of claim 24, wherein the portion of the first dielectric layer adjacent the inner sidewall of each semiconductor fin has a height that is greater than a height of the second dielectric layer.
